(19) United States
(12) Patent Application Publication
(10) Pub. No.: US 2016/0372441 A1
(43) Pub. Date: Dec. 22, 2016

(54) SEMICONDUCTOR DEVICE AND MANUFACTURING METHOD OF SEMICONDUCTOR DEVICE

(71) Applicant: FUJITSU LIMITED, Kawasaki-shi (JP)

(72) Inventors: Hiroshi Kobayashi, Kawasaki (JP); Naoki Ishikawa, Nagano (JP); Shuichi Takeuchi, Chikuma (JP); Takatoyo Yamakami, Nagano (JP); Kimio Nakamura, Suzaka (JP); Tetsuya Takahashi, Nagano (JP)

(73) Assignee: FUJITSU LIMITED, Kawasaki-shi (JP)

(21) Appl. No.: 15/163,076

(22) Filed: May 24, 2016

(30) Foreign Application Priority Data
Jun. 17, 2015 (JP) 2015-122280

(51) Int. Cl. H01L 23/00; H01L 21/56; H01L 21/48; H01L 23/495; H01L 23/31

(52) U.S. Cl. CPC H01L 24/48; H01L 23/49513; H01L 23/4952; H01L 23/49541; H01L 23/3114; H01L 21/4825; H01L 21/565; H01L 2224/48249; H01L 2224/48992; H01L 2224/48997; H01L 2924/3862

(57) ABSTRACT

A semiconductor device includes: a board; a semiconductor chip that is not joined to the board; a wire whose one end is coupled with the semiconductor chip and whose other end is coupled with the board; and a first cover member that covers a first wire coupling portion in which the wire is coupled with the semiconductor chip.

### CROSS-REFERENCE TO RELATED APPLICATION

This application is based upon and claims the benefit of priority of the prior Japanese Patent Application No. 2015-122280, filed on Jun. 17, 2015, the entire contents of which are incorporated herein by reference.

### FIELD

The embodiments discussed herein are related to a semiconductor device and a manufacturing method of a semiconductor device.

### BACKGROUND

A semiconductor device with a hollow structure has been known in which a periphery of a semiconductor chip is hollow. For example, a semiconductor device has been known which includes a sealing portion that fixes a semiconductor chip to a face side of a circuit board so as to form a hollow portion which is integral with a portion provided across a back surface of the semiconductor chip and the face side of the circuit board and with a portion adjacent to at least one peripheral surface other than the back surface of the semiconductor chip.

Further, a semiconductor device has been known in which a board surface is provided with a semiconductor element and a lead, the semiconductor element and the lead is connected with each other by a wire, and those are covered by a metal lid. In this semiconductor device, a periphery of the semiconductor element is formed to be hollow, and a space surrounded by the board and the lid is sealed by a resin.

In a case where a configuration is made such that the semiconductor chip and the board are not joined together and the semiconductor chip is supported by a wire, the wire may be damaged by an impact or vibrations that are applied to the semiconductor device. Particularly, the connecting portion between the wire and the semiconductor chip (hereinafter referred to as wire connecting portion) is fragile, and the wire may break at the wire connecting portion.

The followings are reference documents.
[Document 1] Japanese Laid-open Patent Publication No. 2010-245337 and
[Document 2] Japanese Laid-open Patent Publication No. 63-108755.

### SUMMARY

According to an aspect of the invention, a semiconductor device includes: a board; a semiconductor chip that is not joined to the board; a wire whose one end is coupled with the semiconductor chip and whose other end is coupled with the board; and a first cover member that covers a first wire coupling portion in which the wire is coupled with the semiconductor chip.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram that illustrates a simulation model of a QFN package;

FIG. 2 is a graph that represents a resistance value change due to temperature changes of a resistance element built in a semiconductor chip installed in the QFN package;

FIG. 3 is a cross-sectional view that illustrates a configuration of a semiconductor device according to an embodiment of the techniques of the present disclosure;

FIG. 4A is a diagram that illustrates a manufacturing method of the semiconductor device according to an embodiment of the techniques of the present disclosure;

FIG. 4B is a diagram that illustrates the manufacturing method of the semiconductor device according to the embodiment of the techniques of the present disclosure;

FIG. 4C is a diagram that illustrates the manufacturing method of the semiconductor device according to the embodiment of the techniques of the present disclosure;

FIG. 4D is a diagram that illustrates the manufacturing method of the semiconductor device according to the embodiment of the techniques of the present disclosure;

FIG. 4E is a diagram that illustrates the manufacturing method of the semiconductor device according to the embodiment of the techniques of the present disclosure;

FIG. 5 is a cross-sectional view that illustrates a configuration of a semiconductor device according to an embodiment of the techniques of the present disclosure;

FIG. 6 is a cross-sectional view that illustrates a configuration of a semiconductor device according to an embodiment of the techniques of the present disclosure;

FIG. 7A is a plan view of a semiconductor device according to an embodiment of the techniques of the present disclosure;

FIG. 7B is a cross-sectional view taken along line VIIB-VIIB in FIG. 7A;

FIG. 8 is a cross-sectional view of a semiconductor device according to an embodiment of the techniques of the present disclosure;

FIG. 9 is a cross-sectional view of a semiconductor device according to an embodiment of the techniques of the present disclosure;

FIG. 10A is a plan view of a semiconductor device according to an embodiment of the techniques of the present disclosure;

FIG. 10B is a plan view of the semiconductor device according to the embodiment of the techniques of the present disclosure;

FIG. 11A is a diagram that illustrates a manufacturing method of a semiconductor device according to an embodiment of the techniques of the present disclosure;

FIG. 11B is a diagram that illustrates the manufacturing method of the semiconductor device according to the embodiment of the techniques of the present disclosure;

FIG. 11C is a diagram that illustrates the manufacturing method of the semiconductor device according to the embodiment of the techniques of the present disclosure;

FIG. 11D is a diagram that illustrates the manufacturing method of the semiconductor device according to the embodiment of the techniques of the present disclosure;

FIG. 11E is a diagram that illustrates the manufacturing method of the semiconductor device according to the embodiment of the techniques of the present disclosure;

FIG. 12A is a diagram that illustrates a manufacturing method of a semiconductor device according to an embodiment of the techniques of the present disclosure;

FIG. 12B is a diagram that illustrates the manufacturing method of the semiconductor device according to the embodiment of the techniques of the present disclosure;

FIG. 12C is a diagram that illustrates the manufacturing method of the semiconductor device according to the embodiment of the techniques of the present disclosure; and

FIG. 12D is a diagram that illustrates the manufacturing method of the semiconductor device according to the embodiment of the techniques of the present disclosure.

### DESCRIPTION OF EMBODIMENTS

In a common semiconductor package such as a quad flat non-leaded package (QFN), a semiconductor chip is sealed by a thermosetting mold resin. Because the mold resin and the board (lead frame) have mutually different linear expansion coefficients, the board curves in a phase of thermally curing the mold resin and in a phase of cooling down the mold resin to a normal temperature, and the semiconductor chip joined to the board (lead frame) also curves due to the curving. Further, the board and the semiconductor chip may curve due to the differences in the linear expansion coefficients of members in accordance with the temperature changes in the using environment.

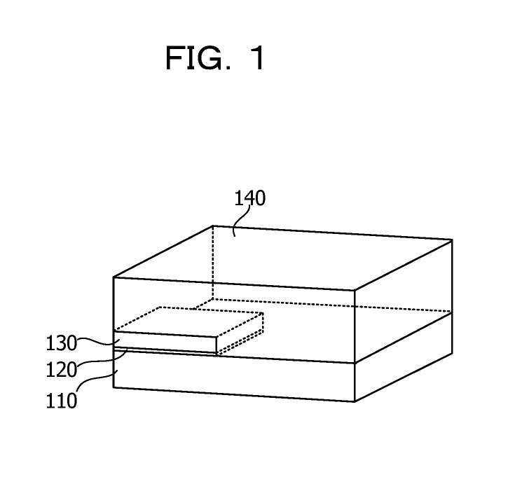

The magnitudes of curve of the QFN package due to heating were obtained by a simulation. FIG. 1 is a model diagram of the QFN package for which the simulation is conducted. One division segment among the QFN package that were divided into four segments was used as the model for the simulation. The simulation model of the QFN package had a structure in which a semiconductor chip 130 joined to the board 110 via an adhesive 120 was sealed by a mold resin 140. An assumed package size was 7 mm×7 mm and a thickness of 1 mm. The size of the semiconductor chip 130 was 3 mm×3 mm. The simulation was conducted while the physical properties of configuration elements were set as table 1 indicated below.

TABLE 1

| | | | Linear expansion |
|---|---|---|---|
| | | Young's modulus | coefficient |
| Material | Poisson's ratio | [GPa] | [ppm] |
| Board | 0.17 | 23 | 15 |
| Mold resin | 0.37 | 13 | 20 |
| Semiconductor | 0.28 | 130 | 2.4 |
| chip | | | |
| Adhesive | 0.37 | 8 | 30 |

In a case where the configuration elements were heated at 150° C., the difference between the lowest point and the highest point of a surface of the semiconductor chip 130, that is, the magnitude of curve that occurred to the semiconductor chip 130 was approximately 20 μm.

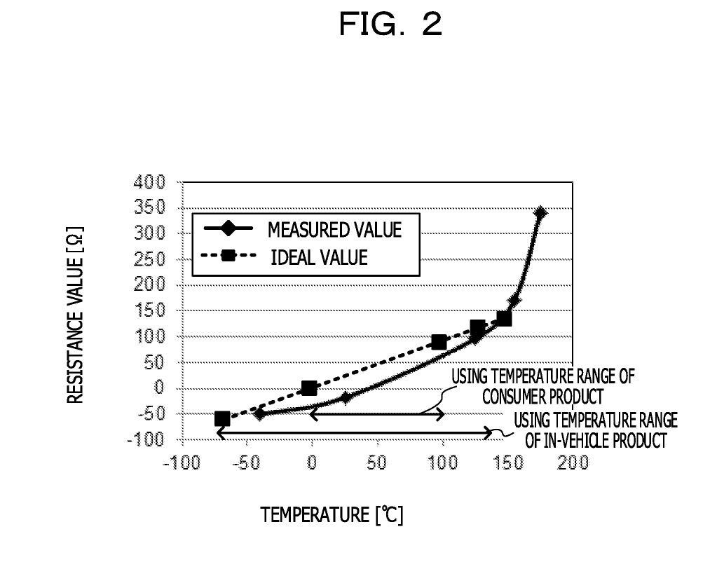

In a case where the curve occurs to the semiconductor chip, electrical characteristics of a circuit element formed on the semiconductor chip fluctuate. FIG. 2 is a graph that represents the resistance value change due to temperature changes of a resistance element built in the semiconductor chip installed in the QFN package. In FIG. 2, the solid line corresponds to measured values, and the broken line corresponds to ideal values. The ideal values are resistance values in a case where the curve due to temperature changes does not occur to the semiconductor chip. As illustrated in FIG. 2, in the semiconductor chip installed in the QFN package, the deviation of the measured values from the ideal values becomes particularly significant in a high temperature range due to the curve caused by temperature changes. That is, resistance values close to the ideal values may be obtained in the using temperature range of consumer products. However, the deviation from the ideal values becomes large in the using temperature range of in-vehicle products. In order to compensate characteristic changes due to such temperature changes, characteristic adjustment for each individual product or adjustment by software is performed in related art. Further, this problem is handled by setting a restriction of using temperatures in a case where the restriction is requested.

Examples of embodiments of the technologies of the present disclosure will hereinafter be described with reference to drawings. The same reference characters are given to the same or equivalent configuration elements in the drawings, and descriptions thereof will not be repeated.

### First Embodiment

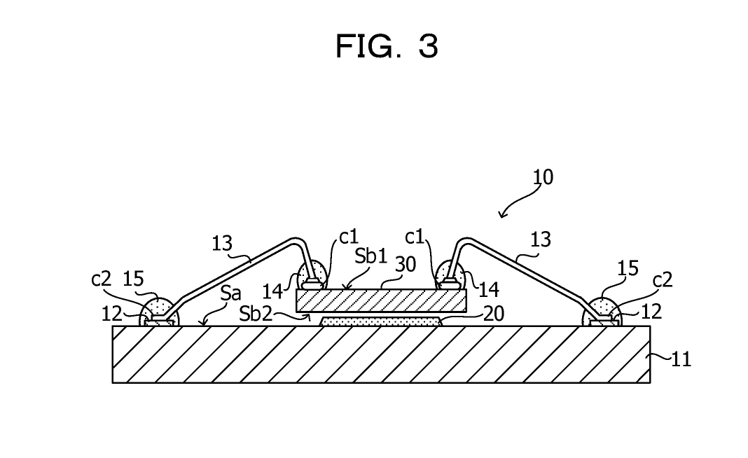

FIG. 3 is a cross-sectional view that illustrates a configuration of a semiconductor device 10 according to an embodiment of the techniques of the present disclosure. In this embodiment, a board 11 is a printed circuit board that has an electrode pad 12 on a surface Sa of a substrate formed of an insulator such as a glass epoxy resin.

A semiconductor chip 30 has an integrated circuit that realizes a desired function, for example. The integrated circuit has circuit elements such as transistors and resistance elements. The semiconductor chip 30 is arranged on the surface Sa side of the board 11 but is not joined to the board 11.

An electrically releasable adhesive member 20 is provided in the position that corresponds to a position in which the semiconductor chip 30 is arranged on the surface Sa of the board 11. The electrically releasable adhesive member 20 has characteristics that application of an electric current causes an electrochemical reaction on an interface with an adherend and adhesive strength thereby lowers. As an example of the electrically releasable adhesive member 20, ElectRelease™ from TAIYO WIRE CLOTH CO., LTD may preferably be used. The electrically releasable adhesive member 20 is used for temporary joining between the semiconductor chip 30 and the board 11. FIG. 1 illustrates a case where separation is caused on the interface between the semiconductor chip 30 and the electrically releasable adhesive member 20 and the joining between the semiconductor chip 30 and the board 11 is thereby released. In this case, a back surface Sb2 of the semiconductor chip 30 may or may not contact with the electrically releasable adhesive member 20. Separation may be caused on the interface between the board 11 and the electrically releasable adhesive member 20, and the joining between the semiconductor chip 30 and the board 11 may thereby be released.

Each of plural wires 13 is configured with a conductor such as gold (Au), aluminum (Al), or copper (Cu), for example. One end of the wire 13 is connected with an electrode pad (not illustrated) formed on a surface Sb1 of the semiconductor chip 30, and the other end is connected with an electrode pad 12 formed on the surface Sa of the board 11. The semiconductor chip 30 is supported in a state where the semiconductor chip 30 is suspended by the wires 13 on the board 11.

A wire connecting portion c1 through which each of the wires 13 is connected with the semiconductor chip 30 is covered by a cover member 14. Similarly, a wire connecting portion c2 through which each of the wires 13is connected with the board 11 is covered by a cover member 15. The cover members 14 and 15 may be configured with a resin material such as an epoxy resin, for example. The cover members 14 and 15 reinforce the wire connecting portions c1 and c2 that are relatively fragile portions of the wire 13. The cover member 14 is preferably formed so as to integrally cover a neck portion of the wire 13 on the semiconductor chip 30 side and an electrode pad (not illustrated) on the semiconductor chip 30. Similarly, the cover member 15 is preferably formed so as to integrally cover a neck portion of the wire 13 on the board 11 side and the electrode pad 12.

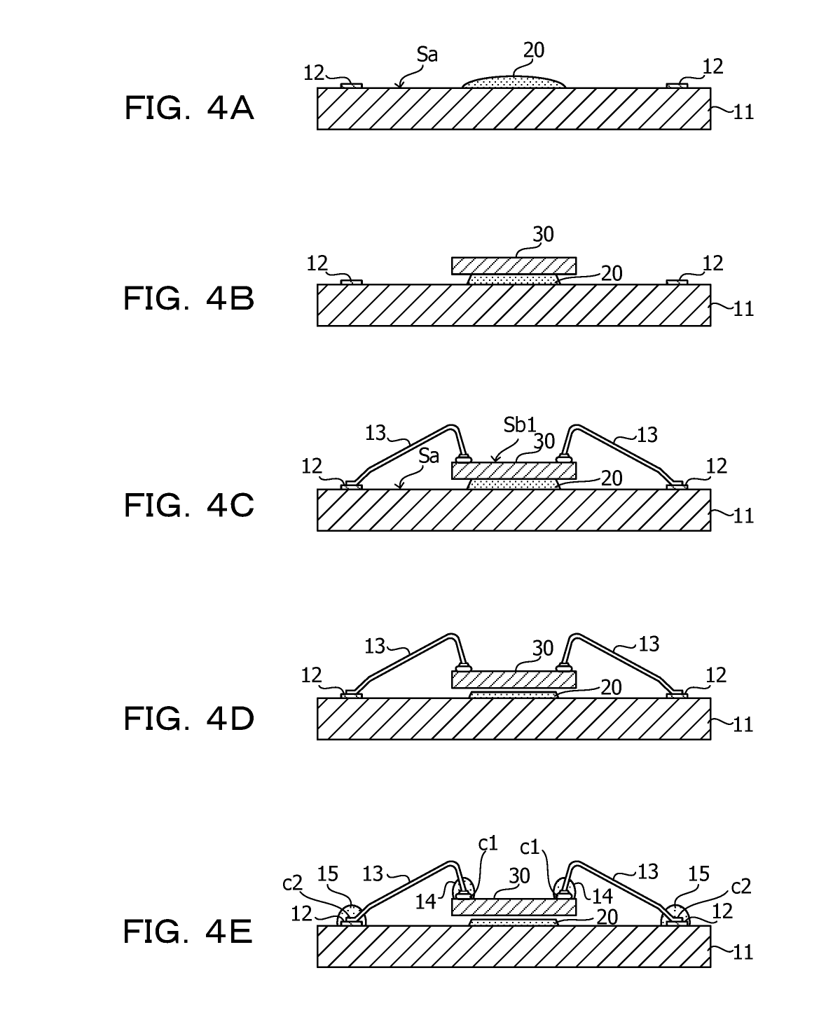

FIGS. 4A to 4E are diagrams that illustrate an example of a manufacturing method of the semiconductor device 10.

First, the electrically releasable adhesive member 20 is supplied to the position that corresponds to a position in which the semiconductor chip 30 is arranged on the surface Sa of the board 11 (FIG. 4A). In a case where ElectRelease™ is used as the electrically releasable adhesive member 20, ElectRelease™ that exhibits a liquid state at a normal temperature is supplied to the board 11 by a coating method.

Next, the semiconductor chip 30 is arranged on the supply position of the electrically releasable adhesive member 20 on the board 11. Subsequently, the electrically releasable adhesive member 20 is cured by a prescribed thermal treatment. In a case where ElectRelease™ is used as the electrically releasable adhesive member 20, a thermal treatment at 180° C. for approximately 1 hour is conducted, for example. Accordingly, the semiconductor chip 30 and the board 11 are temporarily joined together (FIG. 4B).

Next, the semiconductor chip 30 and the board 11 are connected together by the plural wires 13 that are formed of conductors such as gold (Au), aluminum (Al), and copper (Cu). One end of the wire 13 is connected with the electrode pad (not illustrated) formed on the surface Sb1 of the semiconductor chip 30, and the other end of the wire 13 is connected with the electrode pad 12 formed on the surface Sa of the board 11 (FIG. 4C). Connection of the wires 13 is performed by a known ultrasonic bonding scheme. Because the semiconductor chip 30 is joined to the board 11 by the electrically releasable adhesive member 20, the loss of ultrasonic energy output from a bonding tool (not illustrated) may be reduced, and connection of the wire 13 may thus certainly be performed. Hypothetically, in a case where the semiconductor chip 30 were not joined to the board 11 when the connection of the wire 13 is performed, it would be difficult to transmit the ultrasonic energy output from the bonding tool to a wire connecting portion, and many connection failures of the wires 13 might occur.

Next, the electrically releasable adhesive member 20 is energized, and the joining between the semiconductor chip 30 and the board 11 may thereby be released (FIG. 4D). For example, energization for the electrically releasable adhesive member 20 may be performed as follows. The voltage on the anode side of a direct current power source is applied to a silicon board that configures the semiconductor chip 30 via the wires 13 and the electrode pad 12. Meanwhile, an electrode pad (not illustrated) is provided in the supply position of the electrically releasable adhesive member 20 on the board 11, and the voltage on the cathode side of the direct current power source is thereby applied to the electrode pad. As described above, a direct current voltage is applied between the semiconductor chip 30 and the board 11 such that the semiconductor chip 30 side becomes a high potential side. Accordingly, separation occurs on the interface between the semiconductor chip 30 and the electrically releasable adhesive member 20. As a result, the joining between the semiconductor chip 30 and the board 11 is released. A direct current voltage may be applied between the semiconductor chip 30 and the board 11 such that the board 11 side becomes the high potential side. In this case, separation occurs on the interface between the board 11 and the electrically releasable adhesive member 20. In a case where ElectRelease™ is used as the electrically releasable adhesive member 20, a separation reaction is completed at an applied voltage of 10 to 50 V and for a voltage application time of approximately 1 to 20 seconds.

Next, for example, the cover member 14 configured with a resin material such as an epoxy resin is coated onto the wire connecting portion c1 that is the connecting portion between each of the wires 13 and the semiconductor chip 30, and the wire connecting portion c1 of each of the wires 13 is thereby covered by the cover member 14. The cover member 14 is preferably formed so as to integrally cover the neck portion of the wire 13 on the semiconductor chip 30 side and the electrode pad (not illustrated). Similarly, for example, the cover member 15 configured with a resin material such as an epoxy resin is coated onto the wire connecting portion c2 that is the connecting portion between each of the wires 13 and the board 11, and the wire connecting portion c2 of each of the wires 13 is thereby covered by the cover member 15. The cover member 15 is preferably formed so as to integrally cover the neck portion of the wire 13 on the board 11 side and the electrode pad 12. Subsequently, the resin materials that configure the cover members 14 and 15 are cured by a thermal treatment (FIG. 4E).

In the above example, after the joining between the semiconductor chip 30 and the board 11 is released, the wire connecting portions c1 and c2 are respectively covered by the cover members 14 and 15. However, embodiments are not limited to this. That is, before the joining between the semiconductor chip 30 and the board 11 is released, the wire connecting portions c1 and c2 may be respectively covered by the cover members 14 and 15.

As described above, in the semiconductor device 10 according to this embodiment, the semiconductor chip 30 is not joined to the board 11. Accordingly, in a case where the using environment temperature changes, a curve of the semiconductor chip 30 due to the difference in the linear expansion coefficients between the semiconductor chip 30 and the board 11 may be reduced. Consequently, the fluctuations of electrical characteristics of circuit elements such as transistors and resistance elements that are formed on the semiconductor chip 30 due to the change in the using environment temperature may be reduced. Thus, characteristic adjustment for each individual product or adjustment by software that is performed in related art is not requested. Further, because the characteristic fluctuations due to the change in the using environment temperature may be reduced, the semiconductor device 10 may be used in a wide temperature range and may be used as an in-vehicle product. Further, a thermal insulating or thermal dissipating structure is not requested, and the degree of freedom of the implementation position of the semiconductor device 10 increases. This contributes to size reduction and cost reduction of an end product.

Further, in the semiconductor device 10 according to this embodiment, the semiconductor chip 30 is supported in a state where the semiconductor chip 30 is suspended by the plural wires 13. The wire connecting portion c1 that is the connecting portion between each of the wires 13 and the semiconductor chip 30 is reinforced by being covered by the cover member 14. As described above, the wire connecting portion c1 that is a relatively fragile portion of the wire 13 is reinforced by the cover member 14, damage received by the wire 13 due to an impact or vibrations applied to the semiconductor device 10 may thereby be reduced, and the risk of breakage of the wire 13 may thus be reduced. In the semiconductor device 10 according to this embodiment, the wire connecting portion c2 that is the connecting portion between each of the wires 13 and the board 11 is similarly covered by the cover member 15. Accordingly, damage received by the wire 13 due to an impact or vibrations may further be reduced.

Further, in manufacturing steps of the semiconductor device 10 according to this embodiment, the semiconductor chip 30 is temporarily joined to the board 11. Accordingly, wire bonding by an ultrasonic bonding scheme allows the wires 13 to be certainly connected with the semiconductor chip 30. Further, the electrically releasable adhesive member 20 is used for temporary joining between the semiconductor chip 30 and the board 11, and the joining between the semiconductor chip 30 and the board 11 may thus be released easily.

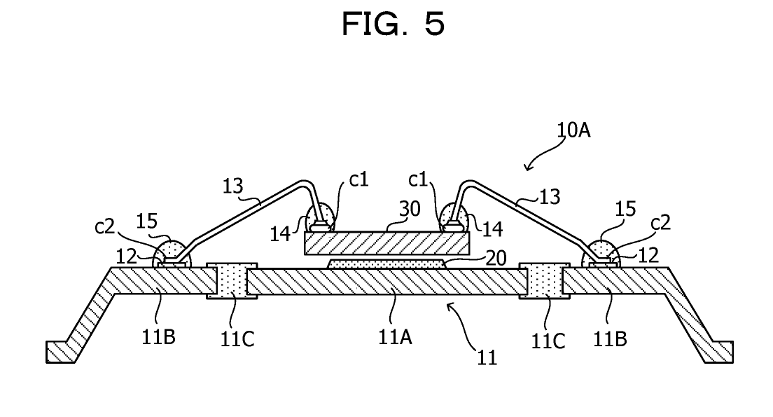

In this embodiment, a case is exemplified where a printed circuit board is used as the board 11. However, a board is not limited to this. The board 11 may have a form of a lead frame. FIG. 5 is a cross-sectional view that illustrates a configuration of a semiconductor device 10A in a case where the lead frame is used as the board 11. The board 11 is configured to include a die pad 11A and a lead 11B that is electrically separated from the die pad 11A. The die pad 11A and the lead 11B are connected together by an insulator 11C such as a resin. The semiconductor chip 30 is arranged on the die pad 11A but not joined to the die pad 11A. The electrically releasable adhesive member 20 is used for temporary joining between the semiconductor chip 30 and the die pad 11A. One end of the wire 13 is connected with an electrode pad (not illustrated) formed on a surface of the semiconductor chip 30, and the other end of the wire 13 is connected with the lead 11B. The wire connecting portion c1 that is the connecting portion between each of the wires 13 and the semiconductor chip 30 is covered by the cover member 14. Similarly, the wire connecting portion c2 that is the connecting portion between each of the wires 13 and the lead 11B is covered by the cover member 15. As described above, even in a case where the lead frame is used as the boar 11, a similar effect to a case of using a printed circuit board may be obtained.

### Second Embodiment

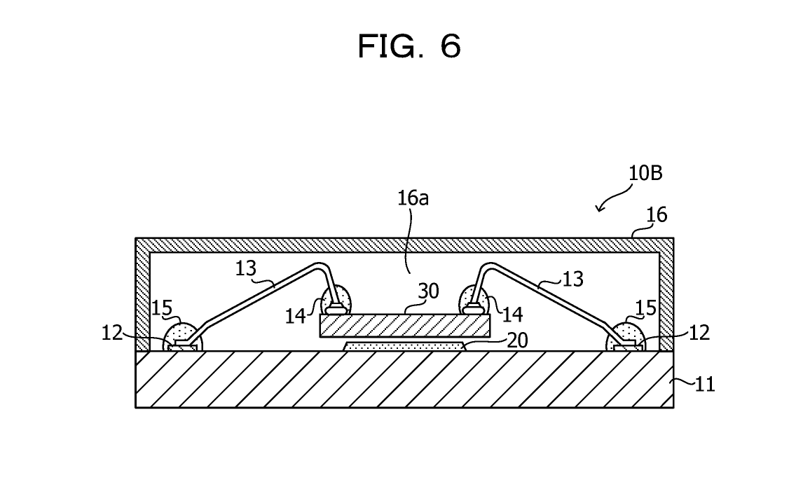

FIG. 6 is a cross-sectional view that illustrates a configuration of a semiconductor device 10B according to a second embodiment of the techniques of the present disclosure. The semiconductor device 10B is different from the semiconductor device 10 according to the first embodiment in the point that the semiconductor device 10B further includes a lid body (lid) 16.

The lid body 16 is joined to the surface Sa of the board 11 by an adhesive, for example, and covers the semiconductor chip 30 and the wires 13. That is, the semiconductor chip 30 and the wires 13 are housed in a housing space 16a that is formed with the lid body 16. Although not particularly limited, examples of the materials for configuring the lid body 16 may include metal such as aluminum (Al) and copper (Cu), ceramics, plastics, and so forth. In manufacturing steps of the semiconductor device 10B, the lid body 16 is mounted on the board 11 after a step of respectively covering the wire connecting portions c1 and c2 by the cover members 14 and 15 (see FIG. 4E).

As described above, the semiconductor chip 30 and the wires 13 are housed in an internal portion of the lid body 16, and a structure is thereby obtained in which the semiconductor chip 30 and the wires 13 are not exposed to the outside, thus facilitating handling.

### Third Embodiment

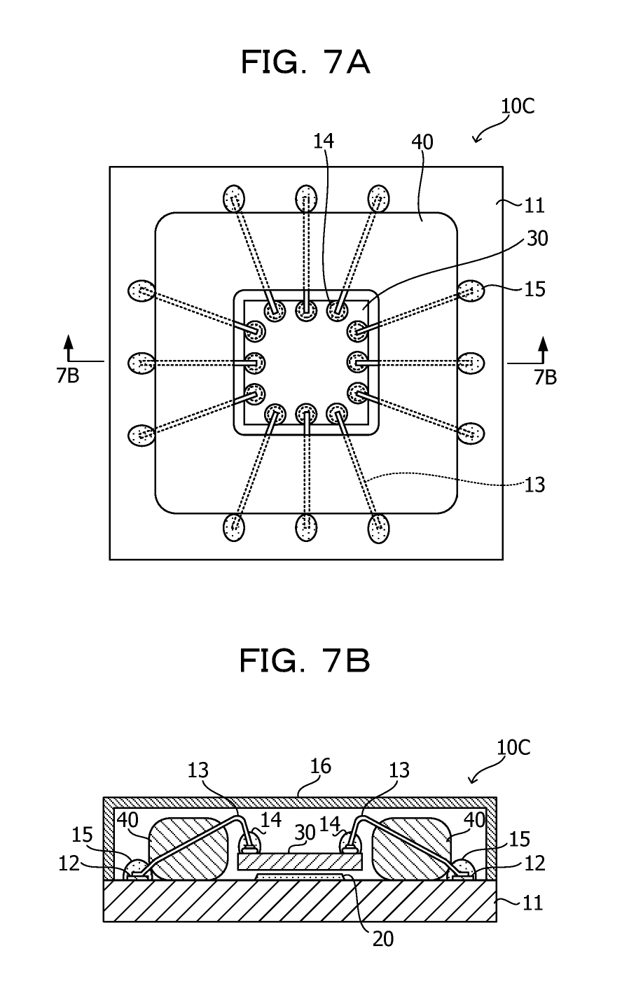

FIG. 7A is a plan view of a semiconductor device 10C according to a third embodiment of the techniques of the present disclosure, and FIG. 7B is a cross-sectional view taken along line VIIB-VIIB in FIG. 7A. The semiconductor device 10C has the lid body 16 that houses the semiconductor chip 30 and the wires 13, similarly to the semiconductor device 10B according to the above second embodiment. Further, the semiconductor device 10C further includes a low-elasticity member 40 that is provided on the board 11. As illustrated in FIG. 7A, the low-elasticity member 40 has an annular external form that surrounds an outer periphery of the semiconductor chip 30, for example. Large portions of the wires 13 other than the portions covered by the cover members 14 and 15 are embedded in an internal portion of the low-elasticity member 40.

A material of the low-elasticity member 40 is configured with a material with a lower elastic modulus than common mold resins that are used for the lid body 16, the QFN package, and so forth. The Young's modulus of the low-elasticity member 40 is preferably equal to or lower than 100 MPa. Examples of materials that are preferably used for the low-elasticity member 40 may include silicone rubber, urethane foam, and so forth.

In manufacturing steps of the semiconductor device 10C, the low-elasticity member 40 is formed later than a step of connecting the wires 13 with the semiconductor chip 30 and the board 11 (see FIG. 4C). The low-elasticity member 40 is formed before or after the wire connecting portions c1 and c2 of the wires 13 are respectively covered by the cover members 14 and 15.

In a case where the low-elasticity member 40 is not provided, the semiconductor chip 30 may collide with an internal wall of the lid body 16 due to an impact or vibrations, and an impact in such collision may damage the wires 13. In the semiconductor device 10C according to the third embodiment, the low-elasticity member 40 is provided so as to surround the outer periphery of the semiconductor chip 30. Accordingly, movement of the semiconductor chip 30 due to an impact or vibrations may be restricted. Consequently, collision of the semiconductor chip 30 with the internal wall of the lid body 16 may be avoided. Further, because the low-elasticity member 40 is configured with the material with a lower elastic modulus than the lid body 16, an impact may be reduced in a case where the semiconductor chip 30 collides with the low-elasticity member 40, and damage received by the wires 13 may thus be reduced. Further, because the wires 13 are protected by being embedded in the internal portion of the low-elasticity member 40, damage received by the wire 13 due to an impact or vibrations may further be reduced.

The low-elasticity member 40 is not limited to an integral form, which is illustrated in FIG. 7A, but may be in a form with plural portions that are mutually separated in the outer periphery in the semiconductor chip 30. That is, the low-elasticity member 40 may have a discontinuous annular shape that surrounds the outer periphery of the semiconductor chip 30. Further, in a case where handling is not difficult, the lid body 16 may be omitted from the semiconductor device 10C.

### Fourth Embodiment

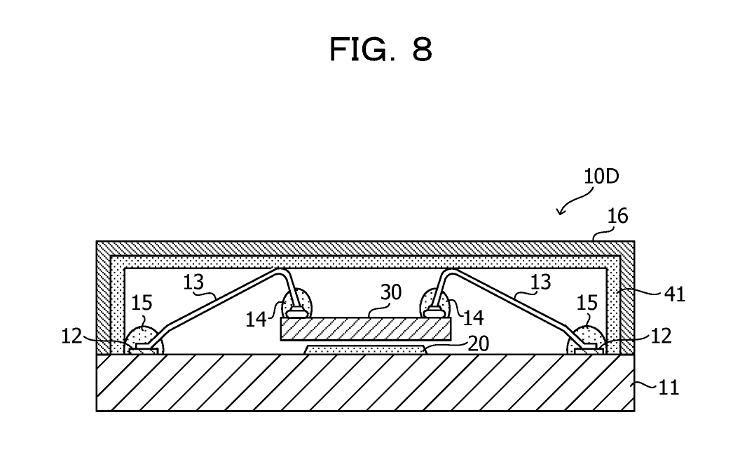

FIG. 8 is a cross-sectional view of a semiconductor device 10D according to a fourth embodiment of the techniques of the present disclosure. The semiconductor device 10D has a configuration in which a low-elasticity member 41 is arranged on the internal wall of the lid body 16, instead of arranging the low-elasticity member 40 in the outer periphery of the semiconductor chip 30 in the semiconductor device 10C according to the above third embodiment. That is, in the semiconductor device 10D according to the fourth embodiment, the internal wall of the lid body 16 is covered by the low-elasticity member 41. A material of the low-elasticity member 41 is configured with a material with a lower elastic modulus than common mold resins that are used for the lid body 16, the QFN package, and so forth. The Young's modulus of the low-elasticity member 41 is preferably equal to or lower than 100 MPa. Examples of materials that are preferably used for the low-elasticity member 41 may include silicone rubber, urethane foam, and so forth.

In the semiconductor device 10D, even in a case where the semiconductor chip 30 collides with the internal wall of the lid body 16 due to an impact or vibrations, because the internal wall of the lid body 16 is covered by the low-elasticity member 41, the impact in collision may be reduced compared to a case where the internal wall of the lid body 16 is not covered by the low-elasticity member 41. Accordingly, damage received by the wire 13 due to an impact or vibrations applied to the semiconductor device 10D may be reduced.

### Fifth embodiment

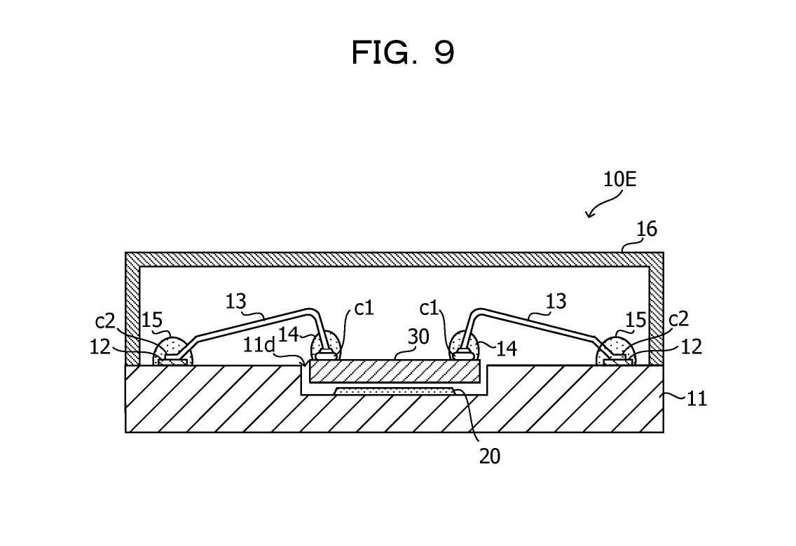

FIG. 9 is a cross-sectional view of a semiconductor device 10E according to a fifth embodiment of the techniques of the present disclosure. In the semiconductor device 10E, the board 11 has a recess 11d in the surface Sa. The size of an opening of the recess 11d is slightly larger than the size of the semiconductor chip 30. The semiconductor chip 30 is housed in a space formed by the recess 11d and is surrounded by an internal wall surface of the recess 11d. The electrically releasable adhesive member 20 that temporarily joins the semiconductor chip 30 and the board 11 together is provided on a bottom surface of the recess 11d.

In manufacturing steps of the semiconductor device 10E, after the electrically releasable adhesive member 20 is supplied to the bottom surface of the recess 11d, the semiconductor chip 30 is arranged on the supply position of the electrically releasable adhesive member 20. Subsequently, the electrically releasable adhesive member 20 is cured by conducting a prescribed thermal treatment. Accordingly, the semiconductor chip 30 and the board 11 are temporarily joined together. After the wires 13 are connected with the semiconductor chip 30 and the board 11, the electrically releasable adhesive member 20 is energized, and the joining between the semiconductor chip 30 and the board 11 is thereby released.

In the semiconductor device 10E, the semiconductor chip 30 is housed in the space formed by the recess 11d of the board 11. Thus, movement of the semiconductor chip 30 due to an impact or vibrations applied to the semiconductor device 10E may be restricted. The movement of the semiconductor chip 30 is restricted, and damage received by the wire 13 due to an impact or vibrations may thereby be reduced.

In a case where handling is not difficult, the lid body 16 may be omitted from the semiconductor device 10E.

### Sixth Embodiment

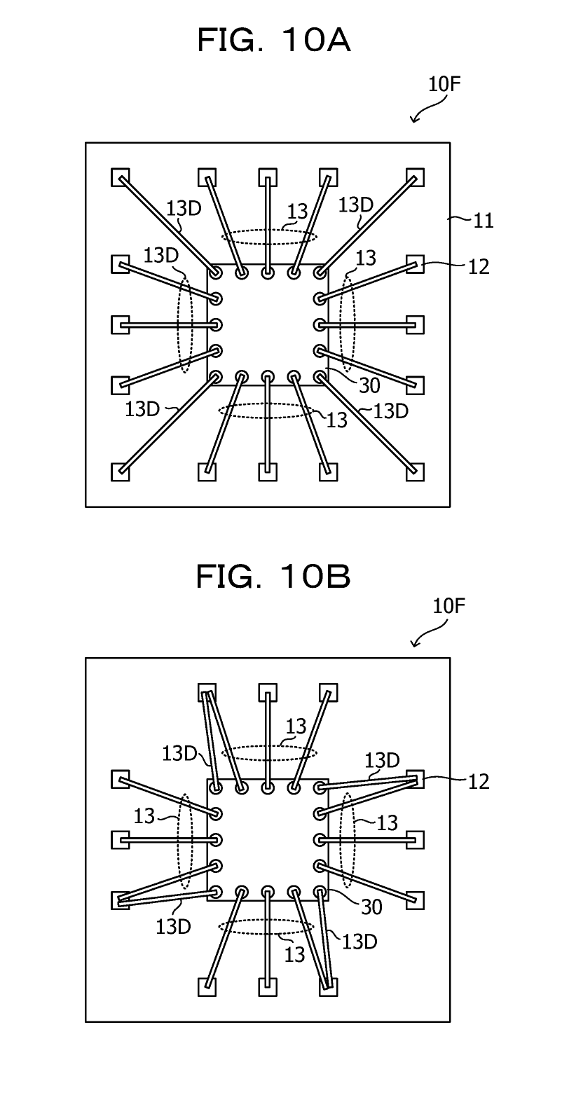

FIGS. 10A and 10B are plan views that illustrate a configuration of a semiconductor device 10F according to a sixth embodiment of the techniques of the present disclosure. In the semiconductor device 10F, at least one of plural wires that are connected with the semiconductor chip 30 and the board 11 is configured as a dummy wire 13D. FIGS. 10A and 10B exemplify four dummy wires 13D that are connected with corner portions of the semiconductor chip 30. However, the number and arrangement of the dummy wires 13D may appropriately be changed. The dummy wire 13D is a wire that does not contribute to an operation of a circuit formed in the semiconductor chip 30. That is, the dummy wire 13D is not a wire that is used for the purpose of electrical connection between the semiconductor chip 30 and the board 11 but is a wire that is simply used for the purpose of supporting the semiconductor chip 30. On the other hand, the wires 13 for wiring other than the dummy wires 13D electrically connect the semiconductor chip 30 with the board 11 and also serve to support the semiconductor chip 30.

As described above, the dummy wires 13D are provided other than the wires 13 for wiring, which are requested for operations of circuits formed in the semiconductor chip 30, and the load allocated to one wire may thereby be reduced. Accordingly, damage received by the wire 13 for wiring due to an impact or vibrations applied to the semiconductor device 10F may be reduced.

In a case where it is difficult to secure a space for forming an electrode pad for the dummy wire 13D on the board 11, as illustrated FIG. 10B, the dummy wire 13D may be connected with the electrode pad 12 with which the wire 13 for wiring is connected.

Further, the dummy wire 13D may be configured with a different material from the wire 13 for wiring. For example, a gold wire may be used as the wire 13 for wiring, and an aluminum wire which is more reasonable and whose elastic modulus is higher than the gold wire may be used as the dummy wire 13D. The aluminum wire is used as the dummy wire 13D, and the increase in the cost in accordance with the increase in the number of wires may thereby be suppressed. An aluminum wire or copper wire may also be used as the wire 13 for wiring. Further, a wire with a larger wire diameter than the wire 13 for wiring may be used as the dummy wire 13D.

Although not illustrated by FIGS. 10A and 10B, similarly to the semiconductor devices according to the above-described first to fifth embodiments, wire connecting portions of the wires 13 for wiring and the dummy wires 13D on the semiconductor chip 30 side and the board 11 side are preferably covered by cover members.

### Seventh Embodiment

In the first to sixth embodiments, cases are exemplified where the electrically releasable adhesive member 20 is used for temporary joining between the semiconductor chip 30 and the board 11. However, temporary joining between the semiconductor chip 30 and the board 11 may be performed by other schemes.

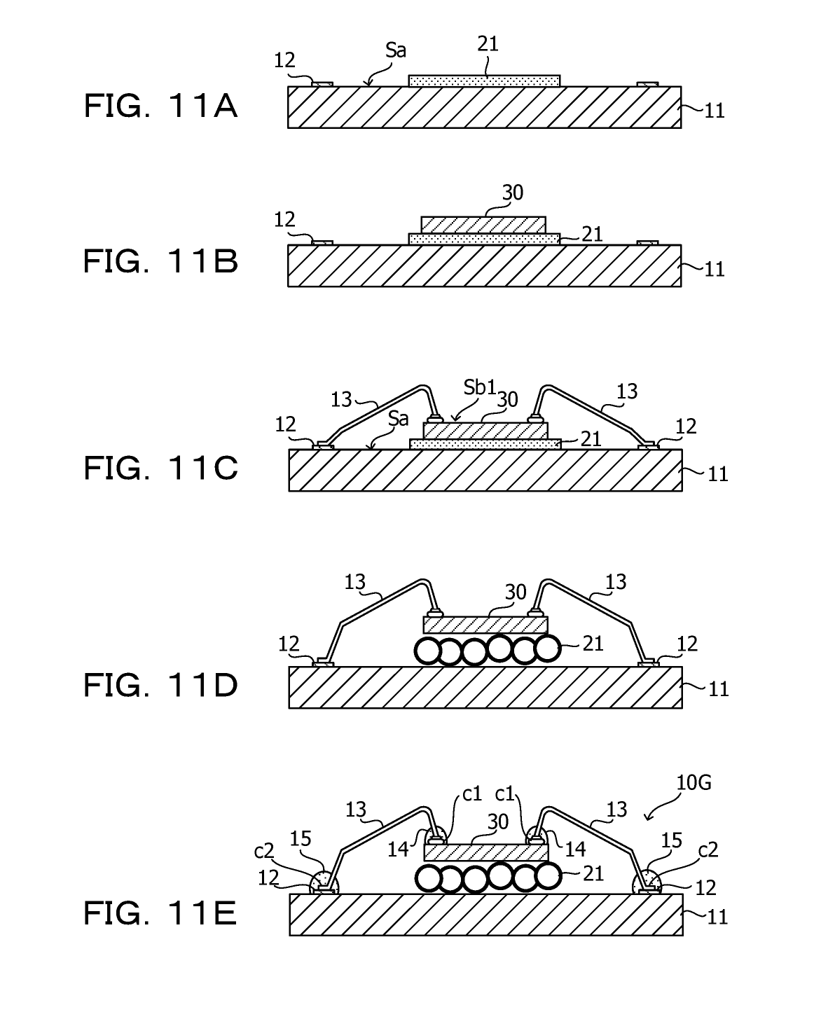

FIGS. 11A to 11E are diagrams that illustrate a manufacturing method of a semiconductor device 10G (see FIG. 11E) according to a seventh embodiment of the techniques of the present disclosure, which includes a step of joining the semiconductor chip 30 and the board 11 together without using the electrically releasable adhesive member 20.

First, a thermally releasable adhesive member 21 is supplied to the position that corresponds to a position in which the semiconductor chip 30 is arranged on the surface Sa of the board 11 (FIG. 11A). The thermally releasable adhesive member 21 is a member which has adhesiveness on both sides at a normal temperature and whose adhesive force is lowered by heating. As an example of the thermally releasable adhesive member 21, REVALPHA® from NITTO DENKO CORPORATION may preferably be used. REVALPHA is a sheet-shaped member and may be used similarly to a common double-sided adhesive sheet.

Next, the semiconductor chip 30 is arranged on a supply position of the thermally releasable adhesive member 21 on the board 11. The adhesive force of the thermally releasable adhesive member 21 temporarily joins the semiconductor chip 30 and the board 11 together (FIG. 11B).

Next, the semiconductor chip 30 and the board 11 are connected together by the plural wires 13 that are formed of conductors such as gold (Au), aluminum (Al), and copper (Cu). One end of the wire 13 is connected with an electrode pad (not illustrated) formed on the surface Sb1 of the semiconductor chip 30, and the other end of the wire 13 is connected with the electrode pad 12 formed on the surface Sa of the board 11 (FIG. 11C). Connection of the wires 13 is performed by a known ultrasonic bonding scheme. Because the semiconductor chip 30 is joined to the board 11 by the thermally releasable adhesive member 21, the loss of ultrasonic energy output from a bonding tool (not illustrated) may be reduced, and connection of the wire 13 may thus certainly be performed.

Next, the thermally releasable adhesive member 21 is heated, and the joining between the semiconductor chip 30 and the board 11 is thereby released (FIG. 11D). In a case where above REVALPHA® is used as the thermally releasable adhesive member 21, the thermally releasable adhesive member 21 foams by heating at approximately 100° C., as illustrated in FIG. 11D. This reduces the adhesive force on adhering surfaces on both of the semiconductor chip 30 side and the board 11 side to approximately zero, and the joining between the semiconductor chip 30 and the board 11 is thereby released.

Next, for example, the cover member 14 configured with a resin material such as an epoxy resin is coated onto the wire connecting portion c1 that is the connecting portion between each of the wires 13 and the semiconductor chip 30, and the wire connecting portion c1 is thereby covered by the cover member 14. The cover member 14 is preferably formed so as to integrally cover the neck portion of the wire 13 on the semiconductor chip 30 side and an electrode pad (not illustrated). Next, for example, the cover member 15 configured with a resin material such as an epoxy resin is coated onto the wire connecting portion c2 that is the connecting portion between each of the wires 13 and the board 11, and the wire connecting portion c2 is thereby covered by the cover member 15. The cover member 15 is preferably formed so as to integrally cover the neck portion of the wire 13 on the board 11 side and the electrode pad 2. Subsequently, the resin materials that configure the cover members 14 and 15 are cured by a thermal treatment (FIG. 11E).

In the above example, after the joining between the semiconductor chip 30 and the board 11 is released, the wire connecting portions c1 and c2 are respectively covered by the cover members 14 and 15. However, embodiments are not limited to this. That is, before the joining between the semiconductor chip 30 and the board 11 is released, the wire connecting portions c1 and c2 may be respectively covered by the cover members 14 and 15.

As described above, the thermally releasable adhesive member 21 is used to perform temporary joining between the semiconductor chip 30 and the board 11, and the joining between the semiconductor chip 30 and the board 11 may thus be released more easily.

### Eighth embodiment

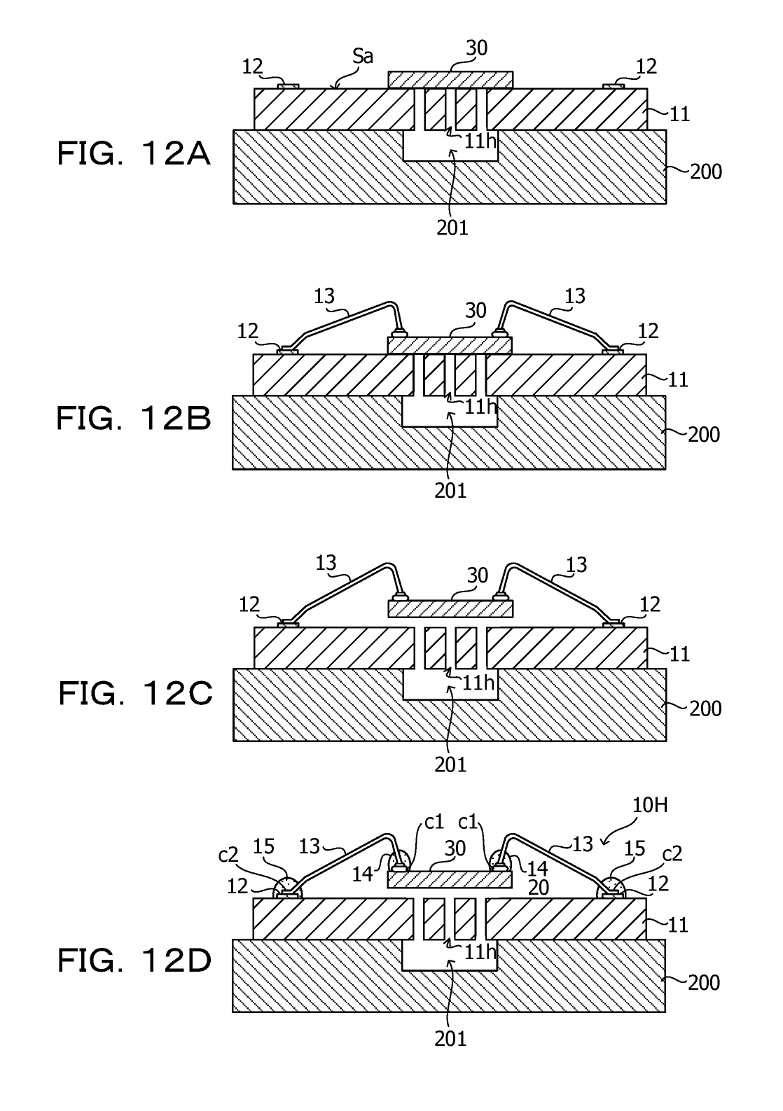

FIGS. 12A to 12D are diagrams that illustrate a manufacturing method of a semiconductor device 10H (see FIG. 12D) according to an eighth embodiment of the techniques of the present disclosure, which includes a step of joining the semiconductor chip 30 and the board 11 together without using the electrically releasable adhesive member 20.

In the semiconductor device 10H, the board 11 has plural through holes 11h in the position that corresponds to a position in which the semiconductor chip 30 is arranged. First, the board 11 is placed on a stage 200 that has a vacuum suction mechanism. Here, positioning is performed such that the through holes 11h of the board 11 are arranged in a forming position of a suction hole 201 of the stage 200. Next, the semiconductor chip 30 is arranged on forming positions of the through holes 11h of the surface Sa of the board 11. Subsequently, the vacuum suction mechanism of the stage 200 is actuated to cause an internal portion of the suction hole 201 to become a vacuum state. Accordingly, the through holes 11h of the board 11 also become the vacuum state, the semiconductor chip 30 is drawn and attached to the surface Sa of the board 11, and the semiconductor chip 30 and the board 11 are temporarily joined together (FIG. 12A).

Next, while the vacuum state of the internal portion of the suction hole 201 is maintained, the semiconductor chip 30 and the board 11 are connected together by the plural wires 13 that are formed of conductors such as gold (Au), aluminum (Al), and copper (Cu). One end of the wire 13 is connected with an electrode pad (not illustrated) formed on the surface Sb1 of the semiconductor chip 30, and the other end of the wire 13 is connected with the electrode pad 12 formed on the surface Sa of the board 11 (FIG. 12B). Connection of the wires 13 is performed by a known ultrasonic bonding scheme. Because the semiconductor chip 30 is joined to the board 11 by the vacuum suction mechanism of the stage 200, the loss of ultrasonic energy output from a bonding tool (not illustrated) may be reduced, and connection of the wire 13 may thus certainly be performed.

Next, the vacuum state of the internal portion of the suction hole 201 of the stage 200 is released, and the internal portion of the suction hole 201 is thereby returned to the atmospheric pressure. Accordingly, the joining between the semiconductor chip 30 and the board 11 is released (FIG. 12C).

Next, for example, the cover member 14 configured with a resin material such as an epoxy resin is coated onto the wire connecting portion c1 that is the connecting portion between each of the wires 13 and the semiconductor chip 30, and the wire connecting portion c1 is thereby covered by the cover member 14. The cover member 14 is preferably formed so as to integrally cover the neck portion of the wire 13 on the semiconductor chip 30 side and the electrode pad (not illustrated). Next, for example, the cover member 15 configured with a resin material such as an epoxy resin is coated onto the wire connecting portion c2 that is the connecting portion between each of the wires 13 and the board 11, and the wire connecting portion c2 is thereby covered by the cover member 15. The cover member 15 is preferably formed so as to integrally cover the neck portion of the wire 13 on the board 11 side and the electrode pad 12. Subsequently, the resin materials that configure the cover members 14 and 15 are cured by a thermal treatment (FIG. 12D).

In the above example, after the joining between the semiconductor chip 30 and the board 11 is released, the wire connecting portions c1 and c2 are respectively covered by the cover members 14 and 15. However, embodiments are not limited to this. That is, before the joining between the semiconductor chip 30 and the board 11 is released, the wire connecting portions c1 and c2 may be respectively covered by the cover members 14 and 15.

As described above, the vacuum suction mechanism is used to perform temporary joining between the semiconductor chip 30 and the board 11, and the joining between the semiconductor chip 30 and the board 11 may thus be released more easily.

The configurations of the semiconductor devices and the processes in the manufacturing methods of the semiconductor devices according to the above-described first to eighth embodiments may appropriately be combined.

The semiconductor devices 10 and 10A to 10H are examples of semiconductor devices of the techniques of the present disclosure. The semiconductor chip 30 is one example of a semiconductor chip of the techniques of the present disclosure. The wire 13 is one example of a wire of the techniques of the present disclosure. The wire connecting portion c1 is one example of a first wire connecting portion of the techniques of the present disclosure, and the wire connecting portion c2 is one example of a second wire connecting portion of the techniques of the present disclosure. The cover member 14 is one example of a first cover member of the techniques of the present disclosure, and the cover member 15 is one example of a second cover member of the techniques of the present disclosure. The lid body 16 is one example of a lid body of the techniques of the present disclosure. The low-elasticity members 40 and 41 are examples of low-elasticity members of the techniques of the present disclosure. The recess 11d is one example of a recess of the techniques of the present disclosure. The electrically releasable adhesive member 20 is one example of an electrically releasable adhesive member of the techniques of the present disclosure. The thermally releasable adhesive member 21 is one example of a thermally releasable adhesive member of the techniques of the present disclosure. The through hole 11h is one example of a through hole of the techniques of the present disclosure. The dummy wire 13D is one example of a dummy wire of the techniques of the present disclosure.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A semiconductor device comprising:
a board;
a semiconductor chip that is not joined to the board;
a wire whose one end is coupled with the semiconductor chip and whose other end is coupled with the board; and
a first cover member that covers a first wire coupling portion in which the wire is coupled with the semiconductor chip.

2. The semiconductor device according to claim 1, further comprising:
a second cover member that covers a second wire coupling portion in which the wire is coupled with the board.

3. The semiconductor device according to claim 2,
wherein the first cover member and the second cover member are configured with a resin material.

4. The semiconductor device according to claim 1, further comprising:
a lid body that houses the semiconductor chip and the wire in an internal portion of the lid body.

5. The semiconductor device according to claim 4, further comprising:
a low-elasticity member that has a lower elastic modulus than the lid body and surrounds an outer periphery of the semiconductor chip,
wherein the wire is embedded in an internal portion of the low-elasticity member.

6. The semiconductor device according to claim 4, further comprising:
a low-elasticity member that covers an internal wall of the lid body and has a lower elastic modulus than the lid body.

7. The semiconductor device according to claim 1,
wherein the board has a recess in a surface, and
the semiconductor chip is arranged in a space that is formed by the recess.

8. The semiconductor device according to claim 1, further comprising:
an electrically releasable adhesive member that is provided between the semiconductor chip and the board and is released by being energized.

9. The semiconductor device according to claim 1, further comprising:
a thermally releasable adhesive member that is provided between the semiconductor chip and the board and is released by heating.

10. The semiconductor device according to claim 1,
wherein the board has a through hole in a position that corresponds to a position in which the semiconductor chip is arranged.

11. The semiconductor device according to claim 1, further comprising:
plural wires whose one ends are coupled with the semiconductor chip and whose other ends are coupled with the board,
wherein at least one of the plural wires is a dummy wire that does not form electrical connection between the semiconductor chip and the board.

12. A manufacturing method of a semiconductor device, the method comprising:
joining a semiconductor chip to a board;
coupling the semiconductor chip and the board together by a wire after the joining;
releasing the joining between the semiconductor chip and the board after the coupling by the wire; and
covering, by a cover member, a coupling portion between the semiconductor chip and the wire.

13. The manufacturing method according to claim 12, further comprising:
covering a coupling portion between the board and the wire.

14. The manufacturing method according to claim 12, further comprising:
joining the semiconductor chip and the board together by using an electrically releasable adhesive member that is released by being energized; and
releasing the joining between the board and the semiconductor chip by energizing the electrically releasable adhesive member.

15. The manufacturing method according to claim 12, further comprising:
joining the semiconductor chip and the board together by using a thermally releasable adhesive member that is released by heating; and
releasing the joining between the board and the semiconductor chip by heating the thermally releasable adhesive member.

16. The manufacturing method according to claim 12, further comprising:
providing the board with a through hole in a position that corresponds to a position in which the semiconductor chip is arranged;
joining the board and the semiconductor chip together by vacuum suction of the semiconductor chip onto a surface of the board via the through hole; and
releasing the joining between the board and the semiconductor chip by releasing the vacuum suction.

17. The manufacturing method according to claim 12, further comprising:
arranging, on the board, a lid body that houses the semiconductor chip and the wire in an internal portion of the lid body after the covering.

18. The manufacturing method according to claim 17, further comprising:
arranging a low-elasticity member that has a lower elastic modulus than the lid body in an outer periphery of the semiconductor chip after coupling the semiconductor chip and the board by a wire; and
embedding the wire in an internal portion of the low-elasticity member.

19. The manufacturing method according to claim 12, further comprising:
providing the board with a recess in a surface; and
arranging the semiconductor chip in the recess in a case of the joining.

20. The manufacturing method according to claim 16, further comprising:
coupling the semiconductor chip and the board together by a dummy wire that does not form electrical connection between the semiconductor chip and the board.
